(19) United States
(12) Patent Application Publication
(10) Pub. No.: US 2014/0118951 A1
(43) Pub. Date: May 1, 2014

(54) INTERPOSER AND PACKAGE ON PACKAGE STRUCTURE

(71) Applicant: Zhen Ding Technology Co., Ltd., Taoyuan (TW)

(72) Inventor: SHIH-PING HSU, Taoyuan (TW)

(73) Assignee: ZHEN DING TECHNOLOGY CO., LTD., Taoyuan (TW)

(21) Appl. No.: 14/064,202

(22) Filed: Oct. 28, 2013

(30) Foreign Application Priority Data
Oct. 26, 2012 (TW) 101139787

(51) Int. Cl. H05K 1/02

(52) U.S. Cl. CPC H05K 1/0206
USPC 361/717; 174/252

(57) ABSTRACT

A heat-dissipating interposer includes an insulating base, a plurality of conductive pillars and a thermal conducting frame. The insulating base includes a first surface and an opposite second surface. The conductive pillars are arranged on the insulating base. The conductive pillars protrude from the second surface. The height of the conductive pillars relative to the second surface is greater than the thickness of the insulating base. The thermal conducting frame is placed on the second surface and receives a heat-generating component. The interposer can be used in a package on package structure.

### BACKGROUND

1. Technical Field

The present disclosure relates to packaging structures for semiconductor devices, particularly to an interposer and a package on package (POP) structure including the interposer.

2. Description of Related Art

In order for a POP structure to attain a high density integrated layout and a small area installation, two electric elements are electrically connected by a plurality of solder balls. The diameter of the solder ball may be in the range from 200 um to 300 um which is quite large. It is difficult to reduce the volume of the POP structure due to the large diameters of the solder ball and the large size of contact pad corresponding to the solder ball. The structural strength and integrity of the connection between the solder ball and the contact pad is not optimal due to the large diameter of the solder ball. So, the reliability of POP structure is not good. In addition, the bottom one of the two electric elements is usually provided between two circuit boards. Heat created by the bottom electric elements is hard to dissipate due to undesirable insulation given by the two circuit boards.

What is needed, therefore, is a POP structure that can overcome the described limitations.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a schematic, cross-sectional view of an interposer according to a first embodiment.

FIG. 2 is a bottom view of the interposer of FIG. 1.

FIG. 3 is a schematic, cross-sectional view of an interposer according to a second embodiment.

FIG. 4 is a schematic, cross-sectional view of an interposer according to a third embodiment.

FIGS. 5-7 are schematic, cross-sectional views of a POP structure.

### DETAILED DESCRIPTION

An interposer and a POP structure will be described with reference to the drawings.

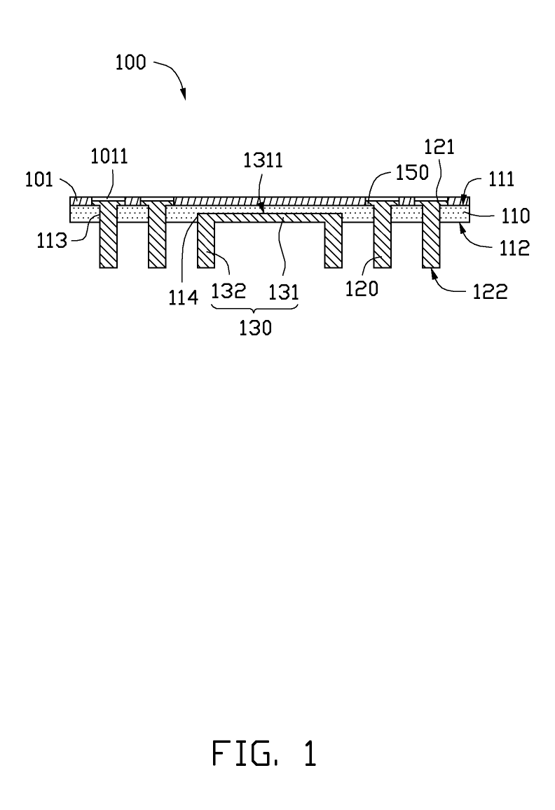

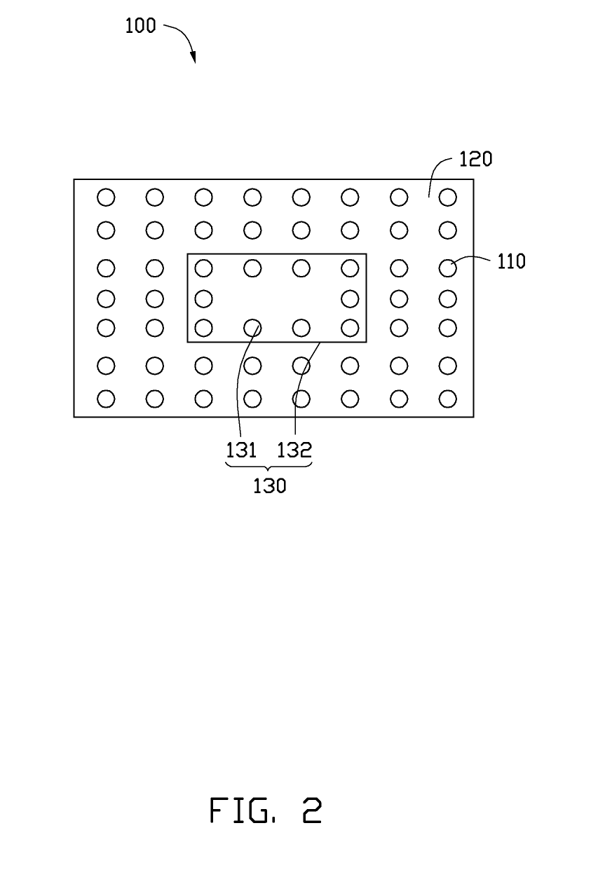

FIGS. 1-2 show an interposer 100 according to a first embodiment. The interposer 100 includes an insulating base 110, a plurality of electric conductive pillars 120, and a thermal conductive frame 130.

The insulating base 110 includes a first surface 111 and a second surface 112 opposite to the first surface 111. A plurality of through holes 113 is defined in the insulating base 110. The through holes 113 are separated from each other. A groove 114 is defined in the first surface 112 to the inside of the insulating base 110.

The electric conductive pillars 120 are aligned with and arranged in the through holes 113. An electric conductive pillar 120 includes a first end face 121 and a second end face 122 opposite to the first end face 121. A height of each electric conductive pillar 120 is greater than the thickness of the insulating base 110 in this embodiment. The first end face 121 and the first surface 111 are coplanar. The second end face 122 protrudes from the second surface 112. The height of the electric conductive pillar 120 relative to the second surface 112 is greater than the thickness of the insulating base 110. Extension direction of the electric conductive pillar 120 is perpendicular to the second surface 112.

A portion of the thermal conductive frame 130 is received in the insulating base 110. The thermal conductive frame 130 includes a top plate 131 and a plurality of thermal conductive pillars 132 perpendicularly interconnected with the top plate 131. The top plate 131 is received in the groove 114. The thermal conductive pillars 132 perpendicularly extend from the border of the top plate 131. There is no thermal conductive pillar 132 formed on the middle area of the top plate 131. Extension direction of the thermal conductive pillar 132 is equal to that of the electric conductive pillar 120. The material of the thermal conductive frame 130 is thermally conductive metal such as copper, aluminum, or silver. In one embodiment, the material of the thermal conductive frame 130 is copper, is the same as that of the electric conductive pillar 120. In one embodiment, the height of the electric conductive pillar 120 relative to the insulating base 110 is equal to that of the thermal conductive pillar 132 relative to the insulating base 110.

The interposer 100 also includes a plurality of first contact pads 150. The first contact pads 150 are formed on the first surface 111. The first contact pads 150 are aligned with the electric conductive pillars 120. The first contact pad 150 is electrically connected with the first end face 121 of an electric conductive pillar 120.

In an alternative embodiment, a solder mask layer 101 is formed on the first surface 111. A plurality of openings 1011 are defined in the solder mask layer 101. The first contact pads 150 are exposed through the openings 1011.

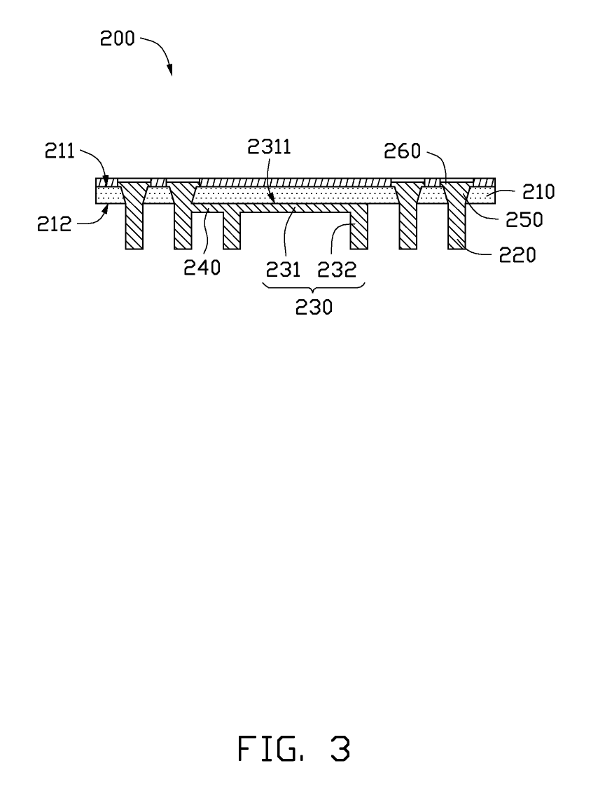

FIG. 3 shows an interposer 200 according to a second embodiment. The structure of the interposer 200 is similar to that of the interposer 100 of the first embodiment. The interposer 200 includes an insulating base 210, a plurality of electric conductive pillars 220, a thermal conductive connector 240, a plurality of conductive vias 250, and a thermal conductive frame 230.

The insulating base 210 includes a first surface 211 and a second surface 212 opposite to the first surface 211. A plurality of through holes 213 is defined in the insulating base 210. The diameter of the through hole 213 gradually reduces from the first surface 211 to the second surface 212.

The electric conductive pillars 220 are aligned with the conductive vias 250. Extension direction of the electric conductive pillars 220 is perpendicular to the second surface 212. A height of each electric conductive pillar 220 is greater than the thickness of the insulating base 210.

The thermal conductive frame 230 is formed on the second surface 212. The thermal conductive frame 230 includes a top plate 231 and a plurality of thermal conductive pillars 232. The top plate 231 includes a top surface 2311 facing away from the thermal conductive pillars 232. The top surface 2311 is in contact with the second surface 212. The top surface 2311 and the second surface 212 are coplanar. The thermal conductive pillars 232 perpendicularly extend from the border of the top plate 231. There is no thermal conductive pillar 232 formed on the middle area of the top plate 131. The material of the thermal conductive frame 230 is thermally conductive metal such as copper, aluminum, or silver. In one embodiment, the material of the thermal conductive frame 230 is copper and is same as that of the electric conductive pillar 220.

The thermal conductive connector 240 is also formed on the second surface 212. The thermal conductive connector 240 interconnects between the thermal conductive frame 230 and an electric conductive pillar 220.

The interposer 200 also includes a plurality of first contact pads 260. The first contact pad 260 is defined on the first surface 211. Each of the first contact pads 260 is electrically connected with a conductive via 250. In one embodiment, the first contact pad 260 and the conductive via 250 corresponding to the first contact pad 260 are integrated.

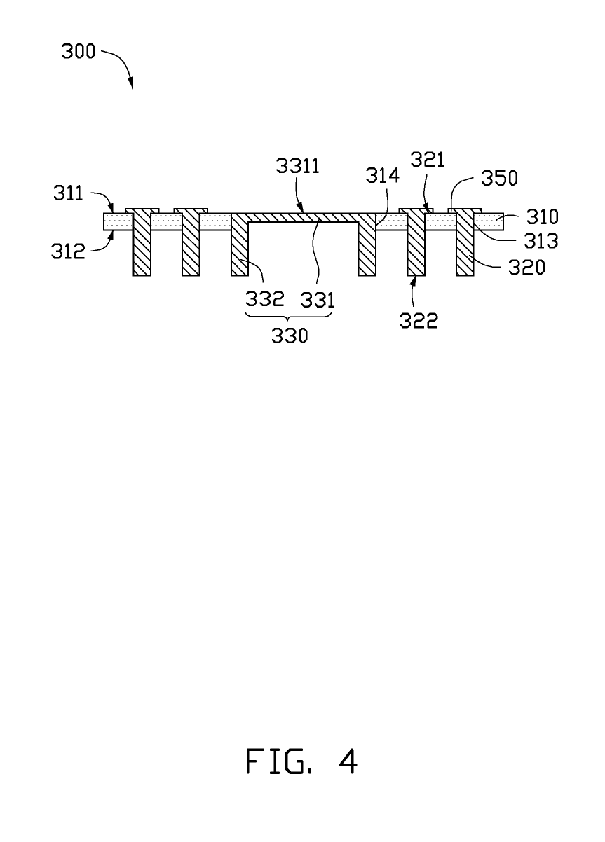

FIG. 4 shows an interposer 300 according to a third embodiment. The structure of the interposer 300 is similar to that of the interposer 100 of the first embodiment. The interposer 300 includes an insulating base 310, a plurality of electric conductive pillars 320, and a thermal conductive frame 330.

The insulating base 310 includes a first surface 311 and a second surface 312 opposite to the first surface 311. A plurality of through holes 313 is defined in the insulating base 310. The through holes 313 are separated from each other. A receiving hole 314 is defined in the second surface 311 through to the first surface 312. The receiving hole 314 is surrounded by the through holes 313.

The electric conductive pillars 320 are aligned with and received in the through holes 313. The electric conductive pillar 320 includes a first end face 321 and a second end face 322 opposite to the first end face 321. The height of each electric conductive pillar 320 is greater than the thickness of the insulating base 310 in this embodiment. The first end face 321 and the first surface 311 are coplanar. The second end face 322 protrudes from the second surface 312. A height of the electric conductive pillar 320 relative to the second surface 312 is greater than the thickness of the insulating base 310.

The thermal conductive frame 330 is partially received in the receiving hole 314. The thermal conductive frame 330 includes a top plate 331 and a plurality of thermal conductive pillars 332 perpendicularly interconnected with the top plate 331. The top plate 331 includes a top surface 3311 facing away from the thermal conductive pillars 332. The top surface 3311 and the first surface 311 are coplanar. The thermal conductive pillars 332 perpendicularly extend from the border of the top plate 331. Extension direction of the thermal conductive pillar 332 is equal to that of the electric conductive pillar 320. The material of the thermal conductive frame 330 is thermally conductive metal such as copper, aluminum, or silver. In one embodiment, the material of the thermal conductive frame 330 is copper, the same as that of the electric conductive pillar 320.

The interposer 300 also includes a plurality of first contact pads 350. The first contact pad 350 is defined on the first surface 311. Each of the first contact pads 350 is aligned with and electrically connected with an electric conductive pillar 320.

In an alternative embodiment, a solder mask layer is formed on the first surface of the second or the third embodiment. A plurality of openings is defined in the solder mask layer. The first contact pads are exposed through the corresponding openings.

The interposer can also includes a thermal conductive connector of the first or the third embodiment. The thermal conductive frame and some of the electric conductive pillars are interconnected through the thermal conductive connectors.

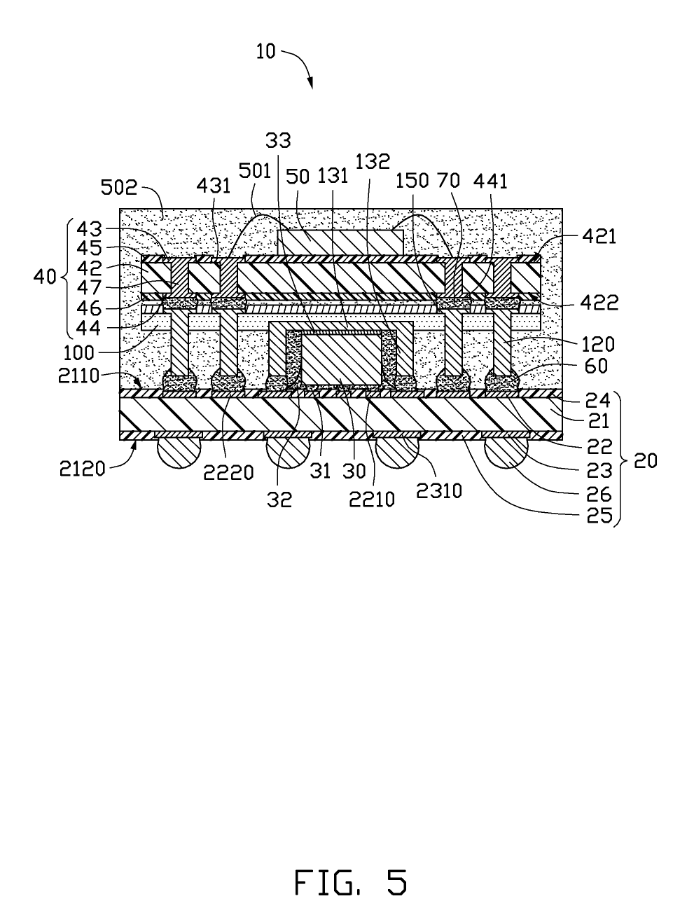

FIG. 5 shows a POP structure 10 according to a fourth embodiment. The POP structure 10 includes a first package substrate 20, a first chip 30, a second package substrate 40, a second chip 50, a first solder 60, a second solder 70, and an interposer of the first embodiment, the second embodiment, or the third embodiment. In this embodiment, an interposer 100 is provided according to the first embodiment.

The first package substrate 20 includes a first base layer 21, a first circuit layer 22, a second circuit layer 23, a first solder mask layer 24, a second solder mask layer 25, and a plurality of solder balls 26. The first circuit layer 22 and the second circuit layer 23 are formed on the opposite surface of the first base layer 21. The first solder mask layer 24 is formed on the surface of the first circuit layer 22. The second solder mask layer 25 is formed on the surface of the second circuit layer 23.

The first base layer 21 is a multilayer substrate. The first base layer 21 includes a plurality of resin layers alternating with a plurality of circuit layers. The first base layer 21 includes a third surface 2110 and a fourth surface 2120 opposite to the third surface 2110. The first circuit layer 22 is formed on the third surface 2110. The second circuit 23 is formed on the fourth surface 2120. In one embodiment, the first circuit layer 22, the second circuit layer 23, and the other circuit layer of the first base layer 21 are electrically connected through a plurality of conductive vias.

Portions of the first circuit layer 22 are exposed through the first solder mask layer 24. The exposed portions of the first circuit layer 22 are defined to be a plurality of third contact pads 2210 and a plurality of fourth contact pads 2220. The third contact pads 2210 are arranged in an array. The third contact pads 2210 are surrounded by the fourth contact pads 2220.

Portions of the second circuit layer 23 are exposed through the second solder mask layer 25. The exposed portions of the second circuit layer 23 are defined to be a plurality of fifth contact pads 2310. The fifth contact pads 2310 are arranged in an array. The third contact pads 2210, the fourth contact pads 2220 and the fifth contact pads 2310 are electrically connected through circuit layers and conductive holes.

Each of the solder balls 26 is aligned with and is attached on a fifth contact pad 2310.

The first chip 30 is packed on the first solder mask layer 24 side of the first package substrate 20 by a flip-chip technology. The first chip 30 is adhered on the first solder mask layer 24 by a first packaging adhesive 32. The first packaging adhesive 32 is made of high heat dissipation material such as thermally conductive adhesive. The first chip 30 includes a plurality of contact pads aligned with the third contact pads 2210. The contact pads of the first chip 30 and the corresponding third contact pads 2210 are electrically interconnected by conductive holes 31. The first chip 30 is received in the thermal conductive frame 130. The first chip 30 and the top plate 131 are interconnected through a heat dissipation bonding sheet 33 for quickly dissipating to the top plate 131 heat created by the first chip 30.

The electric conductive pillars 120 are aligned with and electrically connected with the fourth contact pads 2220 through the first solder 60.

The second package substrate 40 includes two conductive layers. The second package substrate 40 is formed on the interposer 100 and opposite to the first package substrate 20. The second package substrate 40 includes a second base layer 42, a third circuit layer 43, a fourth circuit layer 44, a third solder mask layer 45, and a fourth solder mask layer 46. The third circuit layer 43 and the fourth circuit layer 44 are formed on the opposite surface of the second base layer 42. The third solder mask layer 45 is formed on the surface of the third circuit layer 43. The fourth solder mask layer 46 is formed on the surface of the fourth circuit layer 44.

The second base layer 42 includes a fifth surface 421 and a sixth surface 422 opposite to the fifth surface 421. The third circuit layer 43 is formed on the fifth surface 421. The fourth circuit 44 is formed on the sixth surface 422. The third circuit layer 43 and the fourth circuit layer 44 are electrically connected through a plurality of conductive vias 47. The second base layer 42 is an insulating material or an inner circuit board including circuit layers and insulating layers.

Portions of the third circuit layer 43 are exposed through the third solder mask layer 45. The exposed portions of the third circuit layer 43 are defined to be a plurality of sixth contact pads 431. A chip fixing area is defined on the third solder mask layer 45. The chip fixing area is surrounded by the sixth contact pads 431.

Portions of the fourth circuit layer 44 are exposed through the fourth solder mask layer 46. The exposed portions of the fourth circuit layer 44 are defined to be a plurality of seventh contact pads 441. The seventh contact pads 441 are aligned with the first contact pads 150. The seventh contact pad 441 and the first contact pad 150 are electrically connected through the second solder 70. The sixth contact pads 431 and the seventh contact pads 441 are electrically connected through the third circuit layer 43, the fourth circuit layer 44, and the conductive vias 47.

The second chip 50 is attached on the third solder mask layer 45. In one embodiment, the second chip 50 is a wire bonding chip. The second chip 50 is electrically interconnected with the sixth contact pads 431. In detail, the second chip 50 includes a plurality of soldering contacts and a plurality of soldering wires 501 extended from the soldering contacts. The soldering wires 501 are aligned with and electrically connected with the sixth contact pads 431. The second chip 50 and the third circuit layer 43 are electrically connected through the soldering wires 501.

In one embodiment, the second chip 50 is adhered on the chip fixing area of the third solder mask layer 45 through a adhesive layer. The soldering wires 501 are soldered with the sixth contact pads 431. The material of the soldering wires 501 is gold. The soldering wires 501, the second chip 50, the third solder mask layer 45 and the sixth contact pads 431 are all covered by a second packaging adhesive 502. The second packaging adhesive 502 is black gum or other packaging adhesive.

The interposer 100 and the second package substrate 40 are also covered by the second packaging adhesive 502 if the cross-section area of the first package substrate 20 is greater than that of the interposer 100 and the second package substrate 40. The interposer 100 and the second package substrate 40 are also covered by the second packaging adhesive 502 in this embodiment.

In this embodiment, the first chip 30 is received in the thermal conductive frame 130, thus heat created by the first chip 30 can be dissipated to the thermal conductive frame 130 and out of the POP structure 10. Therefore, the disclosed POP structure 10 provides better heat dissipation.

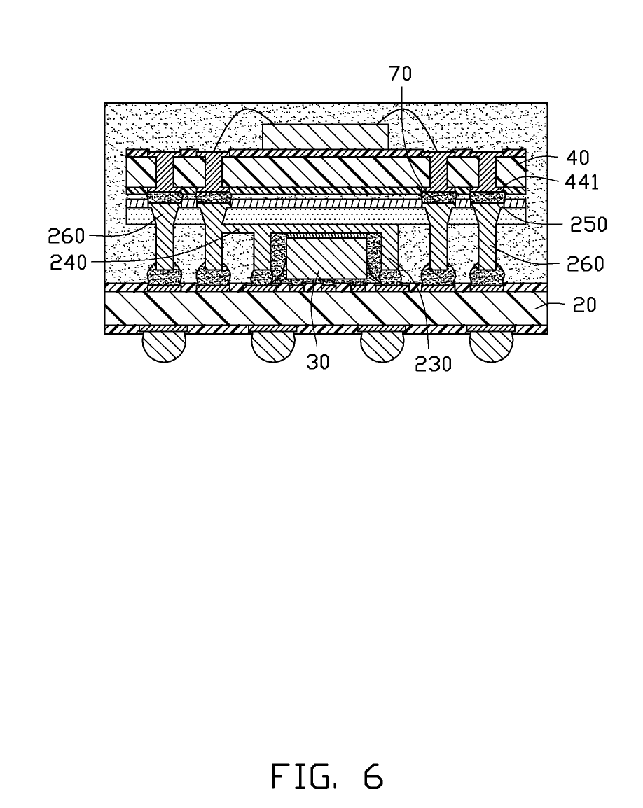

FIG. 6 shows a POP structure including an interposer of the second embodiment. The seventh contact pads 441 are electrically connected with the correspondingacco conductive vias or the first contact pads 250 through the second solder 70. The thermal conductive connector 240 is interconnected between the thermal conductive frame 230 and an electric conductive pillar 220. Therefore, the heat created by the first chip can be dissipated to the electric conductive pillar 220, and thence to the first package substrate 20 and the second package substrate 40 through the thermal conductive frame 230. Thus, the disclosed POP structure 10 provides improved heat dissipation.

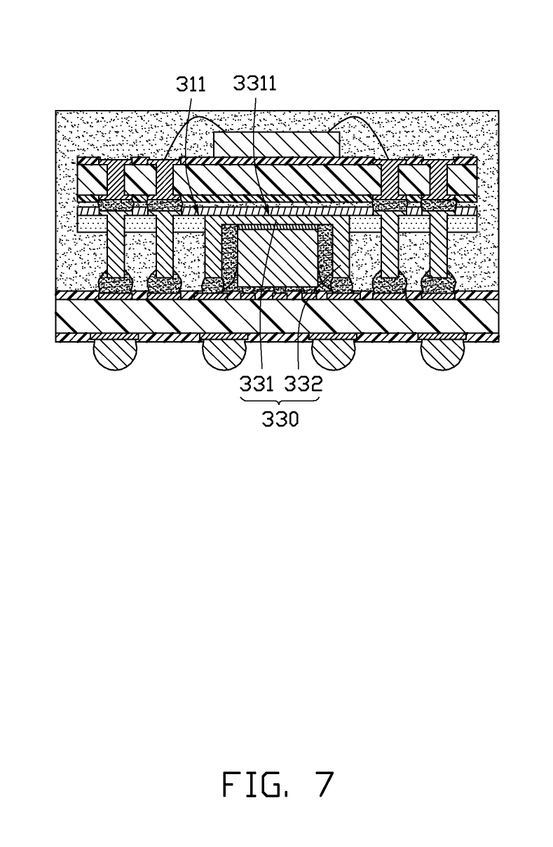

FIG. 7 shows a POP structure including an interposer according to the third embodiment. The top surface 3311 of the top plate 331 and the first surface 311 are coplanar. Therefore, the overall thickness of the POP structure is decreased.

While certain embodiments have been described and exemplified above, various other embodiments will be apparent to those skilled in the art from the foregoing disclosure. The present disclosure is not to be limited to the particular embodiments described and exemplified but is capable of considerable variation and modification without departure from the scope of the appended claims.

What is claimed is:

1. An interposer, comprising:
an insulating base, the insulating base including a first surface and a second surface opposite to the first surface;
a plurality of electric conductive pillars, the electric conductive pillars extending through in the insulating base, extension direction of the electric conductive pillars being perpendicular to the second surface, the height of the electric conductive pillar relative to the second surface being greater than the thickness of the insulating base; and
a thermal conductive frame, the thermal conductive frame attached on one side of the insulating base, the thermal conductive frame being configured for receiving a component.

2. The interposer of claim 1, wherein the thermal conductive frame includes a top plate and a plurality of thermal conductive pillars perpendicularly extending from the top plate, the top plate partially received in the insulating base, extension direction of the thermal conductive pillar being perpendicular to the second surface, a height of the thermal conductive pillar relative to the second surface being greater than the thickness of the insulating base.

3. The interposer of claim 2, wherein a height of the electric conductive pillars relative to the insulating base is equal to that of the thermal conductive pillars relative to the insulating base.

4. The interposer of claim 2, wherein the top plate includes a top surface facing away from the thermal conductive pillars, the top surface and the first surface being coplanar.

5. The interposer of claim 2, wherein the top plate includes a top surface facing away from the thermal conductive pillars, the top surface located within the insulating base.

6. The interposer of claim 1, wherein the electric conductive pillar includes a first end face and a second end face opposite to the first end face, the first end face and the first surface being located on a same plane, the second end face protruding from the second surface.

7. The interposer of claim 6, wherein the interposer includes a plurality of first contact pads, the first contact pads formed on the first surface, the first contact pads being aligned with and electrically connected with the electric conductive pillars.

8. The interposer of claim 1, wherein the interposer includes a thermal conductive connector, the thermal conductive connector interconnected between the thermal conductive frame and an electric conductive pillar.

9. An interposer, comprising:
an insulating base, the insulating base including a first surface and a second surface opposite to the first surface;
a plurality of conductive vias, the conductive vias arranged in the insulating base;
a plurality of electric conductive pillars, the electric conductive pillars being aligned with the conductive vias respectively, extension direction of the electric conductive pillar being perpendicular to the second surface, the height of the electric conductive pillars relative to the second surface being greater than the thickness of the insulating base;
a thermal conductive frame, the thermal conductive frame attached on one side of the insulating base, the thermal conductive frame being configured for receiving a component.

10. The interposer of claim 9, wherein the thermal conductive frame includes a top plate and a plurality of thermal conductive pillars perpendicular extending from the top plate, the top plate includes a top surface facing away from the thermal conductive pillars, the top surface being in contact with the second surface, extension direction of the thermal conductive pillars being perpendicular to the second surface, the height of the thermal conductive pillar relative to the second surface being greater than the thickness of the insulating base.

11. The interposer of claim 10, wherein the height of the electric conductive pillars relative to the insulating base is equal to that of the thermal conductive pillar relative to the insulating base.

12. The interposer of claim 9, wherein the interposer includes a solder mask layer and a plurality of first contact pads, the first contact pads formed on the first surface, the first contact pads being aligned with and electrically connected with the electric conductive pillars, the solder mask layer formed on the first surface, a plurality of openings defining in the solder mask layer, the openings being aligned with the first contact pads, the first contact pads exposed through the corresponding openings.

13. The interposer of claim 9, wherein the interposer includes a thermal conductive connector, the thermal conductive connector interconnected between the thermal conductive frame and one electric conductive pillar.

14. A package on package structure, comprising a first package substrate, a first chip, a second package substrate, a second chip, a first solder, a second solder and an interposer of claim 1; the first package substrate formed on the second surface side of the interposer; the first package substrate including a plurality of third contact pads and a plurality of fourth contact pads; the first chip and the first package substrate being electrically interconnected through the third contact pads; one side of the electric conductive pillars being aligned with and electrically connected with a third contact pad through the first solder; the first chip arranged in the thermal conductive frame; the second package substrate formed on the first surface side of the interposer; the second package substrate including a plurality of seventh contact pads aligned with and electrically interconnected with electric conductive pillars; the other side of the electric conductive pillars being aligned with and electrically connected with a seventh contact pad through the second solder.

15. The interposer of claim 14, wherein the cross-section area of the first package substrate is greater than that of the interposer and the second package substrate, the interposer and, a packaging adhesive covers the second package substrate.

16. The interposer of claim 1, wherein the first package substrate includes a plurality of fifth contact pads, the fifth contact pads being opposite to the third contact pads, a solder ball formed on the fifth contact pad.
